(19) United States
(12) Patent Application Publication
(10) Pub. No.: US 2026/0333590 A1
(43) Pub. Date: Oct. 22, 2026

(54) SYSTEMS AND METHODS FOR MOUNTING ELECTRONIC DEVICES

(71) Applicant: Rivian IP Holdings, LLC, Irvine, CA (US)

(72) Inventors: Heng Kang, Los Angeles, CA (US); Nicholas Athol Keeling, Irvine, CA (US); Xingyu Ren, Irvine, CA (US); Tapan Shirish Mhatre, Cerritos, CA (US); Mayur Sudhir Shinde, Anaheim, CA (US); Puneeth Srikanta Murthy, Irvine, CA (US); Lixiang Wei, Irvine, CA (US)

(21) Appl. No.: 19/184,346

(22) Filed: Apr. 21, 2025

(51) Int. Cl. H05K 3/30; H05K 1/02; H05K 3/34

(52) U.S. Cl. CPC H05K 3/301; H05K 1/0203; H05K 3/341; H05K 2201/10166; H05K 2201/10265; H05K 2201/10409; H05K 2201/10522; H05K 2201/10606

(57) ABSTRACT

A bracket for mounting an electronic device, such as a switching device, to a printed circuit board includes a body configured to interface with at least one electronic device on a first side. The body includes a recess on a second side, and a flexure element is arranged in the recess. A cover is arranged over the flexure element such that the flexure element is arranged between the body and the cover. The flexure element may be pressed to press an interface between the at least one electronic device and a heatsink.

### INTRODUCTION

The present disclosure is directed to a bracket for an electronic device such as a switching device, and more particularly, a bracket that allows the electronic device to be installed in a circuit and interfaced to a heat sink.

### SUMMARY

In some embodiments, the present disclosure is directed to a bracket having a body, a flexure element, and a cover. The body is configured to interface with at least one electronic device on a first side and has a recess on a second side. The flexure element is arranged in the recess, and a cover arranged over the flexure element such that the flexure element is arranged between the body and the cover. In some embodiments, the body includes at least one platform arranged on the first side and configured to interface with the at least one electronic device. In some embodiments, the body includes at least one mounting feature extending from the second side and configured to engage with a printed circuit board assembly (PCBA), wherein the body is comprised of an electrically insulative material. In some embodiments, the body includes a plastic material that is electrically insulative. In some embodiments, the cover includes the same plastic material. In some embodiments, for example, the flexure element may include a metal spring, an elastomeric element, a hinge, or any other suitable element that may have a suitable flexibility and stiffness to deform and transfer force. In some embodiments, the body includes at least one rib arranged in the recess that is configured to maintain a gap between an end of the flexure element and the at least one electronic device. In some embodiments, the body includes at least one retaining feature configured to secure the at least one electronic device. In some embodiments, the body includes at least one cover feature configured to secure the cover against the body. In some embodiments, the flexure element includes at least one section arranged to align with the at least one electronic device on the second side, the flexure element is configured to apply a force on the body, and the body transmits the force to the at least one electronic devices.

In some embodiments, the body includes a first hole, the flexure element includes a second hole that is aligned with the first hole when the flexure element is arranged in the recess, and the cover includes a third hole that is aligned with the first hole when the cover is arranged over the flexure element. For example, the second hole has a lesser diameter than the third hole. In some embodiments, the bracket is configured to receive a fastener having a head and a threaded length. For example, the threaded length is configured to extend through the first, second, and third holes and engage with threads of a heat sink. In a further example, the head is configured to engage with the flexure element to apply a force on the flexure element towards the heat sink.

In some embodiments, the present disclosure is directed to an apparatus having a first platform arranged on a first side configured to receive a first power electronics device, a second platform arranged on the first side configured to receive a second power electronics device, and at least one mounting feature arranged on a second side opposite the first side and extending from the second side to engage a printed circuit board assembly. In some embodiments, the apparatus includes a flexure element arranged on the second side behind the first and second platforms. For example, the flexure element includes two sections configured to apply respective forces on the second side behind the first and second platforms, and the respective forces cause the first and second power electronics devices to press against respective heat sinks. In some embodiments, the apparatus includes a hole extending through the flexure element that is configured to receive a fastener. For example, the fastener is configured to apply a force on the flexure element to cause the flexure element to apply the respective forces on the second side behind the first and second platforms. In some embodiments, the apparatus includes a first rib arranged proximal to a first end of the flexure element and configured to maintain a first gap between the first end and the first power electronics device, and a second rib arranged proximal to a second end of the flexure element, opposite the first end, and configured to maintain a second gap between the second end and the second power electronics device. For example, the first and second gaps maintain minimum creepage paths to mitigate electrical breakdown. In some embodiments, the flexure element includes a middle section arranged between the two sections. For example, the two sections include a first section arranged behind the first platform and having a first curve such that when a force is applied to the middle section in a first direction, the first section applies a first force to the first platform in substantially the first direction. In a further example, the two section include a second section arranged behind the second platform and having a second curve such that when the force is applied to the middle section, the second section applies a second force to the second platform in substantially the first direction.

In some embodiments, the present disclosure is directed to a system having a heat sink and a power electronics printed circuit board. For example, the heat sink includes a plurality of thermal interface regions configured to interface to a plurality of electronic devices. In a further example, the power electronics printed circuit board assembly includes a plurality of brackets. In some embodiments, each bracket includes a respective body configured to interface with at least one electronic device on a first side and having a recess on a second side, a respective flexure element arranged in the respective recess, and a respective cover arranged over the respective flexure element such that the respective flexure element is arranged between the respective body and the respective cover. In some embodiments, each respective body includes at least one rib arranged in the respective recess and configured to maintain a gap between an end of the respective flexure element and the at least one electronic device. In some embodiments, the respective body includes a first hole, the respective flexure element includes a second hole that is aligned with the first hole when the respective flexure element is arranged in the recess, and the respective cover includes a third hole that is aligned with the first hole when the respective cover is arranged over the respective flexure element. For example, the second hole is smaller than the third hole. In some embodiments, the system includes a fastener having a head and a threaded length. For example, the threaded length is configured to extend through the first, second, and third holes and engage with the heat sink, and the head is configured to engage with the flexure element to apply a force on the flexure element towards the heat sink.

### BRIEF DESCRIPTION OF THE DRAWINGS

The present disclosure, in accordance with one or more various embodiments, is described in detail with reference to the following figures. The drawings are provided for purposes of illustration only and merely depict illustrative embodiments. These drawings are provided to facilitate an understanding of the concepts disclosed herein and shall not be considered limiting of the breadth, scope, or applicability of these concepts. It should be noted that for clarity and ease of illustration these drawings are not necessarily made to scale.

FIG. 1 shows a perspective view of an illustrative bracket assembly, in accordance with some embodiments of the present disclosure;

FIGS. 2-3 show perspective exploded views of an illustrative bracket, in accordance with some embodiments of the present disclosure;

FIGS. 4-5 show perspective views of the illustrative bracket of FIG. 2, with and without a cover, in accordance with some embodiments of the present disclosure;

FIGS. 6-7 show front and back exploded views of the illustrative bracket of FIGS. 2-4, in accordance with some embodiments of the present disclosure;

FIGS. 8-10 show top, bottom, and side views of the illustrative bracket of FIGS. 2-6, in accordance with some embodiments of the present disclosure;

FIG. 11 is a flowchart of an illustrative process for forming a bracket assembly, in accordance with some embodiments of the present disclosure;

FIG. 12 is a flowchart of an illustrative process for installing a bracket assembly to interface with a heat sink, in accordance with some embodiments of the present disclosure; and

FIGS. 13-14 show cross-sectional views of an illustrative bracket assembly mounted to a PCBA, and applying pressure to a thermal interface, in accordance with some embodiments of the present disclosure.

### DETAILED DESCRIPTION

In some embodiments, the present disclosure is directed to systems and methods for mounting electronic devices to a printed circuit board (PCB) or PCB assembly (PCBA). For example, in some circumstances, an electronic device (e.g., a power electronics device such as a discrete power switch device) is to be securely mounted on the PCB while ensuring proper mechanical stability. The device should maintain consistent and reliable contact with the thermal interface material to facilitate efficient heat dissipation. Additionally, since the surface of the device maybe classified as a high-voltage surface (e.g., for a power electronics device), it may include adequate electrical insulation from both the PCB and the heat sink to ensure proper operation and compliance with electrical standards. In some embodiments, the present disclosure is directed to a bracket configured to secure the electronic device in place during soldering to the PCB and to ensure consistent pressure is applied to the thermal interface material in a final product. The bracket may provide mechanical stability while maintaining electrical insulation between the PCB and the heat sink. A flexure element (e.g., a spring) may be included, and may have a shape that helps ensure that a central portion of the switch device is consistently and uniformly pressed, preventing over-compression or under-compression of the TIM during installation. In some embodiments, the bracket includes features that facilitate the deployment of thermocouples for testing purposes, enabling accurate thermal performance monitoring.

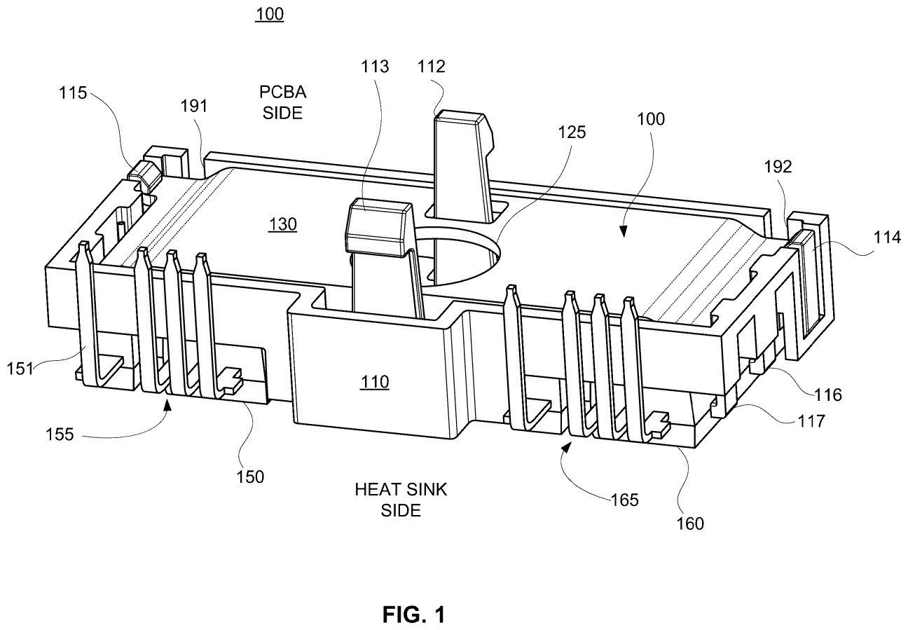

FIG. 1 shows a perspective view of illustrative bracket assembly 100, in accordance with some embodiments of the present disclosure. For context, an illustrative “PCBA side” and illustrative “heat sink side” are shown in FIG. 1. As illustrated, bracket assembly 100 includes a bracket (e.g., the combination of bracket body 110 and cover 130) and power electronics devices 150 and 160. For example, power electronics devices 150 and 160 may include transistors such as MOSFETs having pins (e.g., illustrated by pins 151), and respective surfaces 155 and 165 configured to interface to a heat sink for heat transfer (e.g., heat transfer from power electronics devices 150 and 160 to a heat sink and away from the PCBA). As illustrated, bracket body 110 includes features 112 and 113 (e.g., flexible tabs) configured to interface with and engage a PCBA, features 114 and 115 (e.g., flexible tabs) configured to interface with and engage cover 130, and features 116 and 117 (e.g., flexible tabs) configured to interface with and engage one or more power electronics devices. For example, in some embodiments, one or more of bracket assembly 100 may be installed on a PCBA, using features 112 and 113, and the pins of power electronics devices 150 and 160 may be soldered to suitable terminals of the PCBA. As an illustrative example, each bracket assembly 100 may correspond to a pair of switching devices (e.g., MOSFETs) of a converter, such as a DC-DC converter (e.g., a dual-active bridge (DAB) converter), or other suitable power electronics system. In some embodiments, the bracket includes through-hole 125 configured to accommodate a fastener or other suitable element for applying a force that is transmitted to power electronics devices 150 and 160 (e.g., to push against a heat sink). In some embodiments, bracket assembly 100, or bracket body 110 thereof, includes channels 191 and 192 to accommodate instrumentation, sensors (e.g., temperature sensors such as a thermocouple), wiring, or any combination thereof.

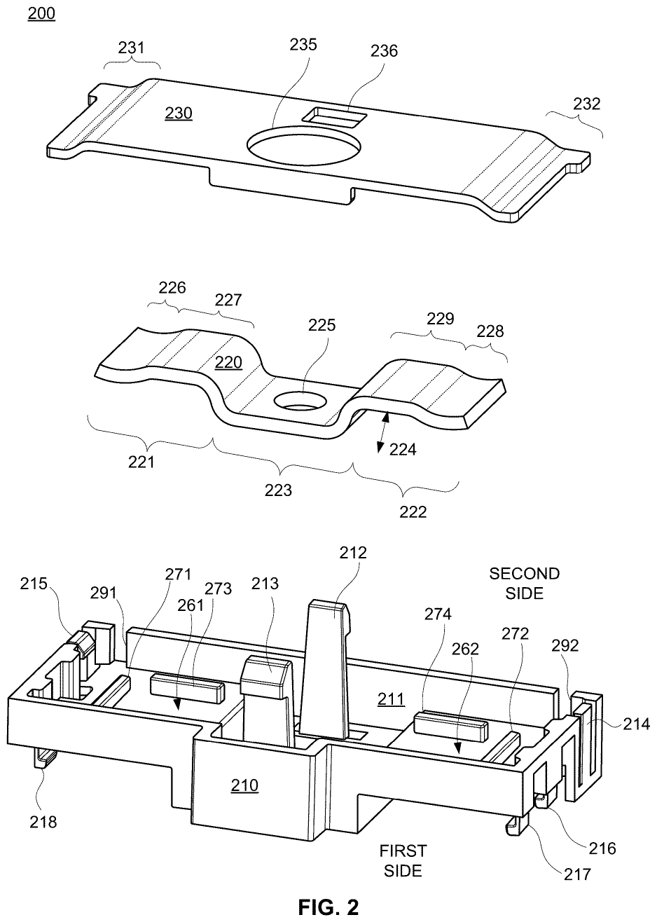

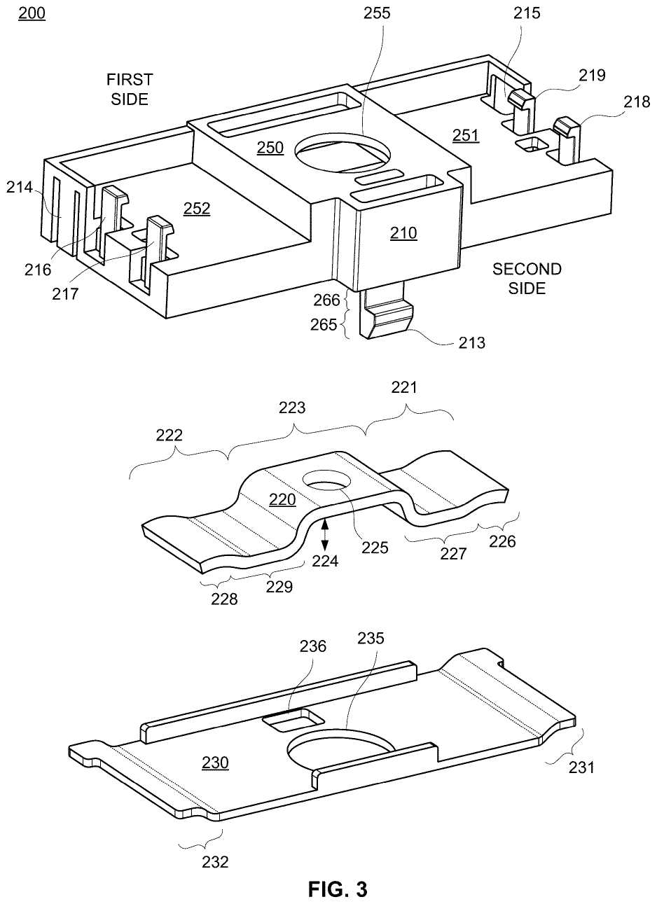

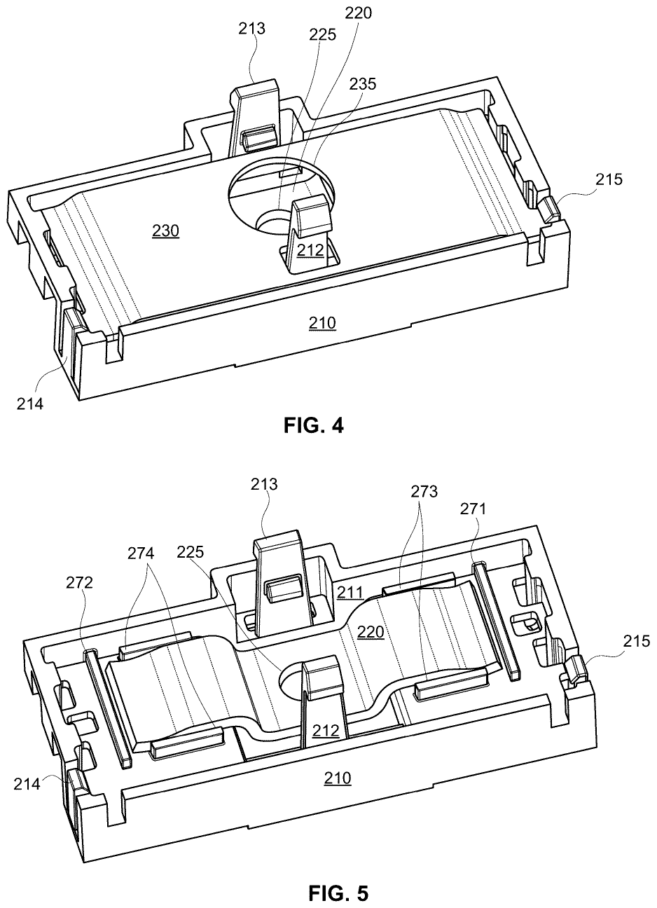

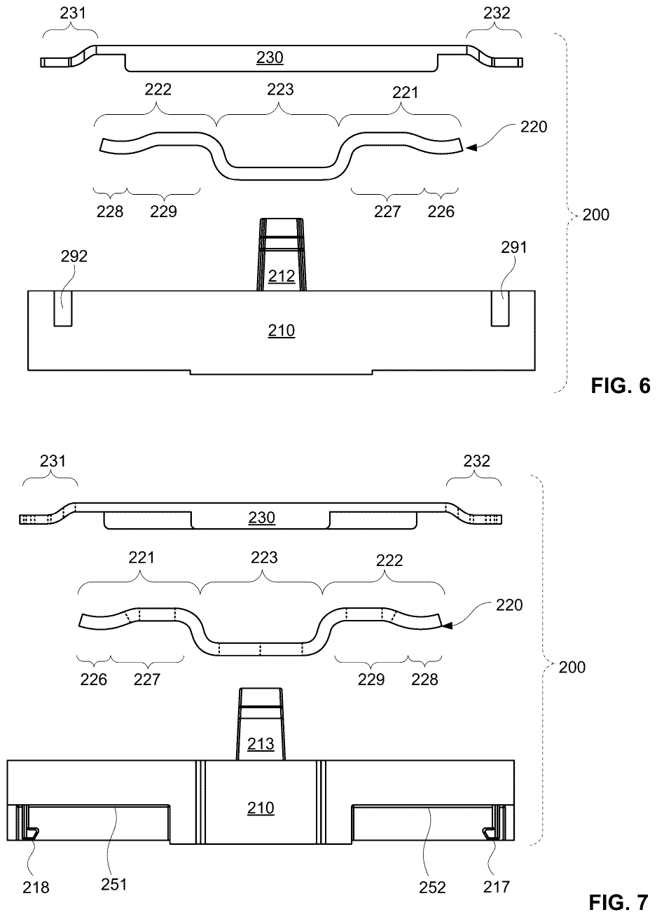

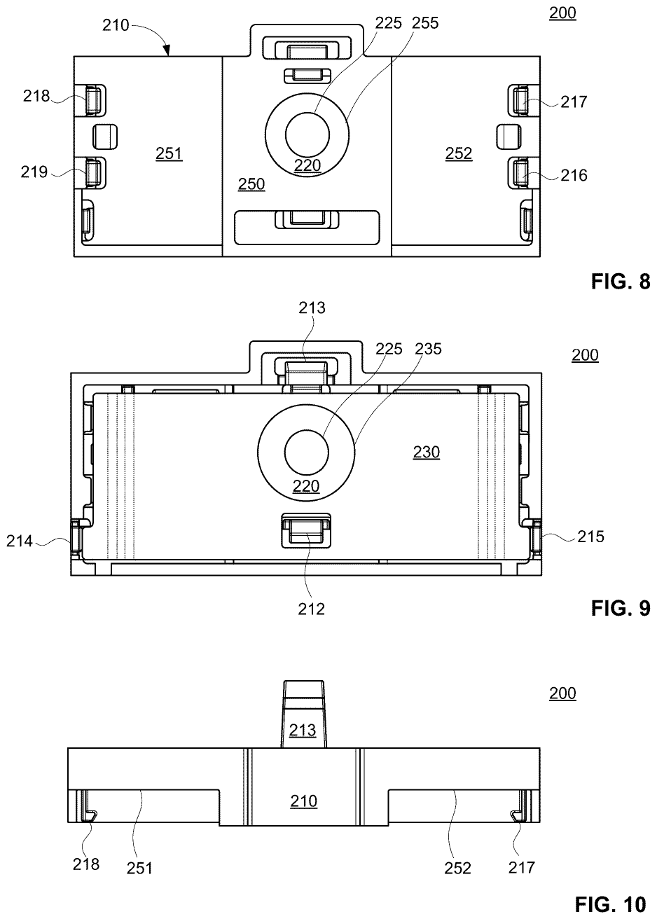

FIGS. 2-3 show perspective exploded views of illustrative bracket 200, in accordance with some embodiments of the present disclosure. FIGS. 4-5 show perspective views of illustrative bracket 200 of FIGS. 2-3, with and without a cover, in accordance with some embodiments of the present disclosure. FIGS. 6-7 show front and back exploded views of illustrative bracket 200 of FIGS. 2-5, with and without a cover, in accordance with some embodiments of the present disclosure. FIGS. 8-10 show top, bottom, and side views of illustrative bracket 200 of FIGS. 2-7, with and without a cover, in accordance with some embodiments of the present disclosure. Bracket 200, which may be the same as the bracket of bracket assembly 100 of FIG. 1, is illustrated in an exploded view to render flexure element 220 clearer, because flexure element 220 is configured to be installed in recess 211 of body 210 and covered by cover 230. For example, flexure element 220 may be installed in recess 211 and may be secured laterally by features 273 and 274 (e.g., ribs, as illustrated, to limit lateral displacement of flexure element 220).

As illustrated in FIG. 2, body 210 include a “first side” and a “second side,” which may be the same as the respective heat sink side and PCBA side of FIG. 1. Body 210, as illustrated, includes features 212 and 213 (e.g., mounting features such as flexible tabs) extending from the second side and configured to interface with and engage a PCBA, features 214 and 215 (e.g., flexible tabs) configured to interface with and engage cover 230, and features 216, 217, 218, and 219 (e.g., flexible tabs) configured to interface with and engage one or more power electronics devices (not shown in FIGS. 2-3). In some embodiments, body 210 includes platforms 251 and 252 (e.g., first and second platforms) arranged on the first side and configured to accommodate respective power electronics devices such as switching devices (e.g., transistors). In some embodiments, body 210 includes hole 255 (e.g., a first hole), which extends through body 210 (e.g., from middle section 250 to recess 211 on the second side opposite platforms 251 and 252). Each of features 212 and 213 may include an extension section (e.g., section 266 illustrated in part in FIG. 3), and locking section 265 (e.g., the hook-shaped section at the end of feature 213 illustrated in FIG. 3). When assembled, power electronics devices are arranged on the first side with pins extending around to the second side where the PCBA is located (e.g., as illustrated by pins 151 of FIG. 1).

In some embodiments, as illustrated in FIG. 2, body 210 includes channels 291 and 292 configured to accommodate instrumentation, sensors (e.g., temperature sensors such as a thermocouple), wiring, or any combination thereof. For example, each of channels 291 and 292 may open from recess 211 to the exterior of body 210. In a further example, during operation or testing, one or more temperature sensors, voltage sensors, any other suitable sensors, or any combination thereof may be mounted or arranged on body 210 and any corresponding wires may be routed out through channel 291, channel 292, or both to processing circuitry. A bracket may, but need not, include channels 291 and 292, and optionally may include any suitable number of channels.

As illustrated, flexure element 220 includes hole 225 (e.g., a second hole) arranged in middle section 223, which is arranged between sections 221 and 222 (e.g., first and second sections). Middle section 223 is offset from sections 221 and 222 by distance 224. Section 221 includes regions 226 and 227. Region 227, as illustrated, is substantially parallel with middle section 223 and offset from middle section 223 by distance 224. Region 226 curves away from region 227 (e.g., back towards middle section 223) and is configured to press against the back of platform 251 (e.g., illustrated by region 261). Similarly, section 222 includes region 229, offset from middle section 223 by distance 224, and region 228 configured to press against region 262 behind platform 252. For example, referencing FIG. 2, if a force is applied downward (e.g., in the orientation illustrated in FIG. 2) to middle section 223, regions 226 and 228 press downward on respective regions 261 and 262, which in turn apply respective forces from platforms 251 and 252 to respective power electronics devices (e.g., against respective TIMs of a heatsink). In an illustrative example, flexure element 220 may include a metal spring, including any suitable metallic material (e.g., steel, stainless steel such as 17-4 stainless steel, or any other suitable metal or alloy). In a further example, hole 225 may align with hole 255 when flexure element 220 is installed, and hole 225 may have a diameter lesser than a diameter of hole 255.

In some embodiments, as illustrated, bracket 200 includes cover 230. For example, because flexure element 220 may include metal (e.g., flexure element 220 may be a metal spring), body 210 and cover 230 may provide electrical insulation between flexure element 220 and conductive elements of a PCBA. If included, cover 230 includes hole 235 (e.g., a third hole) configured to accommodate a fastener, tool, or both, and opening 236 configured to accommodate feature 212 (e.g., which may extend through opening 236 when cover 230 is installed and secured by features 214 and 215 or any other suitable cover features). As illustrated, cover 230 includes section 231 and 232, which extend inwards toward flexure element 220 and are configured to engage with respective features 215 and 214 to secure cover 230 to body 210. In an illustrative example, body 210, cover 230, or both may include any suitable plastic material or composite material (e.g., a high-temperature, electrically insulative plastic, optionally including glass fibers). In a further example, hole 235 may align with hole 225 and hole 255 when cover 230 is installed, and hole 225 may have a diameter lesser than a diameter of hole 235.

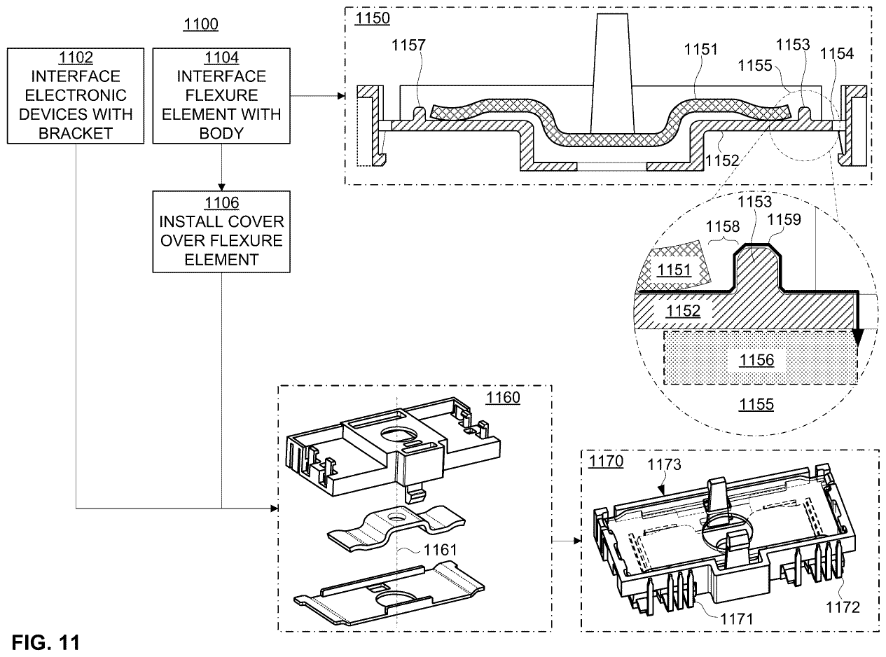

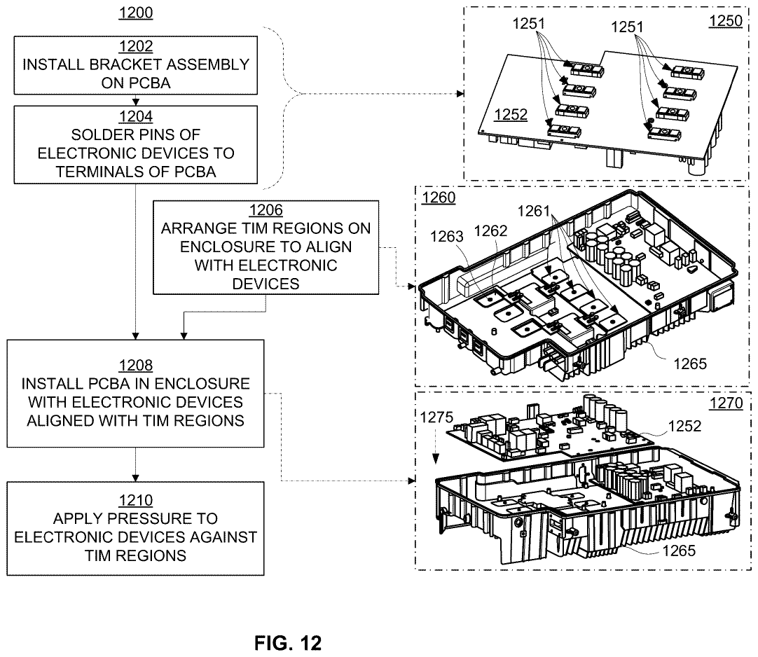

FIG. 11 is a flowchart of illustrative process 1100 for forming a bracket assembly, in accordance with some embodiments of the present disclosure. To illustrate, bracket 200, and aspects thereof, of FIGS. 2-10 may be referred to below.

Step 1102 includes interfacing one or more electronic devices, such as suitable power electronics devices, with a bracket. In some embodiments, step 1102 includes interfacing one or more electronic devices are transistors, such as MOSFETs that are configured to provided switching of power, for example. For example, the devices may each include a body (e.g., encasing circuitry and semiconductor materials) and pins (e.g., to provide electrical access to the semiconductor materials and circuitry). Because such devices may be used as power electronics devices and may generate heat as they operate (e.g., arising from ohmic losses), the devices may include one or more surfaces configured to be coupled to a heatsink. Step 1102 may include mounting an electronic device onto a platform (e.g., platforms 251 or 252 of FIGS. 2-10). In some embodiments, the bracket may include one or more retaining features such as flexible tabs configured to hold the electronic device in place (e.g., features 216-219 of FIG. 210). In some embodiments, the electronic device may extend proud from the bracket. For example, referencing bracket 200, a top surface of the electronic device may lie above middle section 250 when installed, such that when the assembly is installed on a PCB, the electronic device may be more easily interfaced to a heatsink (e.g., without the bracket getting in the way or impeding the interface).

Step 1104 includes interfacing a flexure element with the bracket. In some embodiments, step 1104 includes placing the flexure element in a recess of the bracket (e.g., recess 211 of body 210). In some embodiments, where a cover is included, the flexure element may sit in the recess without any additional securement. In some embodiments, the bracket or body thereof may include one or more ribs or stops to help locate the flexure element and prevent shifting in lateral position (e.g., features 273 and 274). In some embodiments, if no cover is included, the body may include one or more tabs to prevent the flexure element from falling out of the recess, but allow the flexure element to move (e.g., to undergo deformation to apply a force on the back of the platforms).

Step 1106 includes installing a cover over the flexure element. In some embodiments, where a cover is included, the cover may be engaged with the body of the bracket to bind the flexure element in the recess. In some embodiments, the cover also provides electrical insulation. For example, because the flexure element may be metal, such as a metal spring, which may be electrically conductive, the cover may include an insulative material to prevent electrical shorting when the bracket assembly is installed in a PCB, during handling, or both. In some embodiments, the cover and body may be made of the same material (e.g., a molded plastic material).

Panel 1150 illustrates a cross-section of flexure element 1151 interfaced with body 1152, including enlarged section 1155. As illustrated, body 1152 includes one or more ribs (e.g., which may be similar to or the same as ribs 271-274), of which rib 1153 is arranged at an end of flexure element 1151. In some embodiments, rib 1153 and gap 1158 (e.g., between the end of flexure element 1151 and rib 1153) may be designed such that creepage path 1159 is greater than a threshold distance, in compliance with a suitable reference or standard distance (e.g., associated with electrical breakdown over a lifetime of the bracket and bracket assembly), sufficient to minimize or otherwise limit electrical breakdown, based on any other suitable criterion, or any combination thereof. Step 1104 may include arranging flexure element 1151 in a location defined by the one or more ribs (e.g., of which rib 1153 is one), which sets a creepage path on each side (e.g., of which creepage path 1159 is one) to ensure that electrical breakdown is prevented or otherwise less likely to occur. In an illustrative example, creepage path 1159 may correspond to a gap (e.g., between an end of flexure element 1151 and electronic device 1156) of a length greater than a length of gap 1158. To illustrated, a bracket may include a rib at each end of flexure element 1151 (e.g., ribs 1153 and 1157), and optionally ribs to limit displacement or help locate flexure element 1151 in another direction (e.g., into or out of the page), which may be configured to respectively maintain a respective creepage path. The creepage paths may extend from a point of contact between flexure element 1151 and body 1152 and an opening of body 1152 (e.g., opening 1154, which may be open to a platform where an electronic device may be arranged (e.g., at step 1102). The electronic device may operate at a relatively high voltage, for example corresponding to a bridge circuit (e.g., of the primary or secondary side of a DC-DC converter). For example, because flexure element 1151 and electronic device 1156 may be at different voltages (e.g., a voltage difference may exist), creepage path 1159 prevents or otherwise limits current flow (e.g., a short) due to the difference in voltage. In some embodiments, for example, a bracket may include one or more ribs that are incorporated to enhance the creepage distance between a metal spring and the surface of a semiconductor device other suitable electronic device (e.g., a switching device such as a MOSFET or other suitable type of transistor), thereby improving electrical insulation and reducing the likelihood of electrical breakdown.

In an illustrative example, step 1102 may be performed before, after, or during the installation of the spring and cover at step 1104 and 1106. For example, the stack of components may be assembly all at once, such as being lightly pressed together along axis 1161 as illustrated in panel 1160, to form the assembly illustrated in panel 1170 (e.g., including first and second electronic devices 1171 and 1172 interfaced to bracket 1173). In a further example, the electronic devices may be installed first at step 1102, and then the spring and cover may be installed at steps 1104 and 1106. In a further example, the spring and cover may be installed first at steps 1104 and 1106, and then the one or more electronic devices may be installed at step 1102.

FIG. 12 is a flowchart of illustrative process 1200 for installing a bracket assembly to interface with a heat sink, in accordance with some embodiments of the present disclosure. The bracket assembly may be assembled according to process 1100 of FIG. 11, and may include a bracket (e.g., having a body, flexure element, and cover) and one or more electronic devices (e.g., switching devices).

Step 1202 includes installing a bracket assembly on a PCBA. In some embodiments, step 1202 includes engaging one or more mounting features of the bracket with mating features of the PCBA. For example, the mounting features may include flexible tabs that hook into recesses of the PCBA. In a further example, the mounting features may include features 212 and 213 of FIGS. 2-10, which may be configured to extend through one or more recesses (e.g., section 266 extends through respective recesses or one larger recess) of the PCBA and hook on the opposite side of the PCBA (e.g., using locking section 265) to secure the bracket assembly from being pulled off the PCBA. In some embodiments, the arrangement of the PCBA may define a position of the bracket assembly such that pins of the one or more electronic devices are aligned with terminals of the PCBA (e.g., for surface-mount or through hole interfaces). As illustrated in panel 1250, plurality of bracket assemblies 1251 may be interfaced to PCBA 1252. For example, plurality of bracket assemblies 1251 may be snapped into place using respective mounting features at step 1202, such that plurality of bracket assemblies 1251 are held in place for step 1204.

Step 1204 includes soldering pins of the one or more electronic devices to terminals of the PCBA. For example, once the one or more electronic devices are secured to the PCBA via one or more brackets at step 1202, the pins of each electronic device may be soldered to suitable terminals of the PCBA. To illustrate, the PCBA may include one or more bridge circuits (e.g., corresponding to the primary and secondary sides of a transformer of a DC-DC converter), and the electronic devices may include power electronic devices electrically coupled to or otherwise forming the bridge circuits at step 1204.

Step 1206 includes arranging thermal interface material (TIM) regions on an enclosure (or other suitable structure) to align with the one or more electronic devices. In some embodiments, the TIM regions include a gel, flexible material, paste, coating, mat or pad, or any other suitable form and composition of material to provide for heat transfer from an electronic device to a heat sink. In some embodiments, the enclosure functions as the heat sink. For example, the enclosure may be made of a thermally conductive material and may include fins, cooling jackets, any other suitable cooling features, or any combination thereof. By interfacing each electronic devices to a TIM region, the temperature of the electronic device, the PCBA, nearby components of the PCBA, or a combination thereof, may be managed. As illustrated in panel 1260, plurality of TIM regions 1261 may correspond to a plurality of electronic devices of plurality of bracket assemblies 1251 such that when PCBA 1252 is installed in enclosure 1265, plurality of electronic devices of plurality of bracket assemblies 1251 are aligned with plurality of TIM regions 1261. Enclosure 1265 may function as a heatsink itself (e.g., be thermally conductive to a lower temperature boundary), or may otherwise include one or more heatsinks (e.g., one or more separate heat sinks may be mounted to an enclosure). In an illustrative example, TIM regions 1261 may include a silicone pad, or any other suitable thermally conductive material. In a further illustrative example, the plurality of electronic devices of plurality of bracket assemblies 1251 may include a plurality of switching devices or other power electronic devices that may generate heat during operation (e.g., from ohmic losses based on current flows). The power electronics devices, which may include transistors such as MOSFETs, may include a surface configured to reject heat to a heat sink.

Step 1208 includes installing the PCBA in the enclosure (or other suitable structure) with the one or more electronic devices aligned with the TIM regions. In some embodiments, once PCBA 1252 is assembled, PCBA 1252 may be secured in enclosure 1265 (e.g., using one or more fasteners, clips, bushings, grounding connections, electrical isolators, any other suitable components, or any combination thereof). As PCBA 1252 is installed, plurality of electronic devices of plurality of bracket assemblies 1251 may align with, and potentially contact, plurality of TIM regions 1261. For example, as illustrated in panel 1270, PCBA 1252 may be installed in direction 1275 into enclosure 1265 such that plurality of electronic devices of plurality of bracket assemblies 1251 align with, and potentially contact, plurality of TIM regions 1261. As illustrated in panel 1270, plurality of bracket assemblies 1251 are directed downward, and thus are not visible in the perspective view illustrated in panel 1270. In some embodiments, the interface pressure between plurality of electronic devices of plurality of bracket assemblies 1251 and plurality of TIM regions 1261 affects heat transfer with a greater pressure corresponding to a lesser interfacial resistance and thus greater thermal conductivity. Because step 1208 includes mounting the entirety of PCBA 1252, in some circumstances, the contact pressure between the plurality of electronic devices and plurality of TIM regions 1261 may be difficult to control accurately, repeatably, and consistently among the interfaces. In some such circumstances, process 1200 may include step 1210 to further manage the interfaces. As illustrated, each TIM region of plurality of TIM regions 1261 includes TIM 1262 and hole 1263 (e.g., a threaded hole configured to engage with a threaded fastener).

Step 1210 includes applying pressure to the one or more electronic devices against the TIM regions. In order to control the thermal interface between plurality of electronic devices of plurality of bracket assemblies 1251 and plurality of TIM regions 1261, pressure may be applied to each bracket assembly, or components thereof. In some embodiments, step 1210 includes compressing or otherwise deforming a flexure element to apply forces on the respective electronic devices. In an illustrative example, because step 1210 may be performed after the PCBA is assembled and installed, the heat transfer interface to the heat sink may be managed more independently and consistently. In some embodiments, process 1200 allows the PCBA assembly and installation to be separate from the thermal interface management. For example, force may be applied to the flexure element after assembly and installation to ensure desired thermal contact with the heat sink (e.g., without being wholly dependent on the PCBA installation at step 1208 to manage the thermal interface).

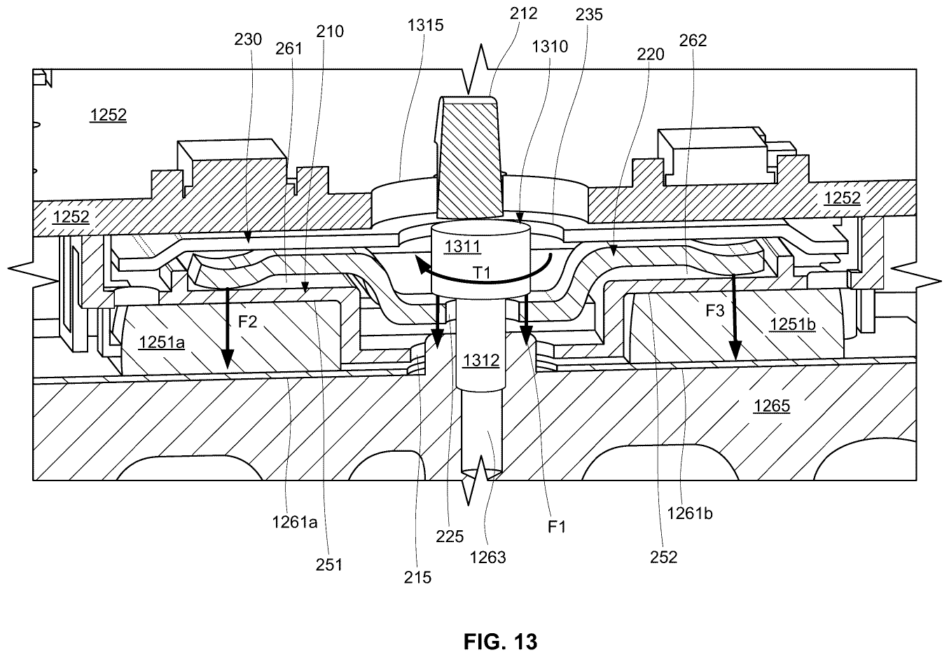

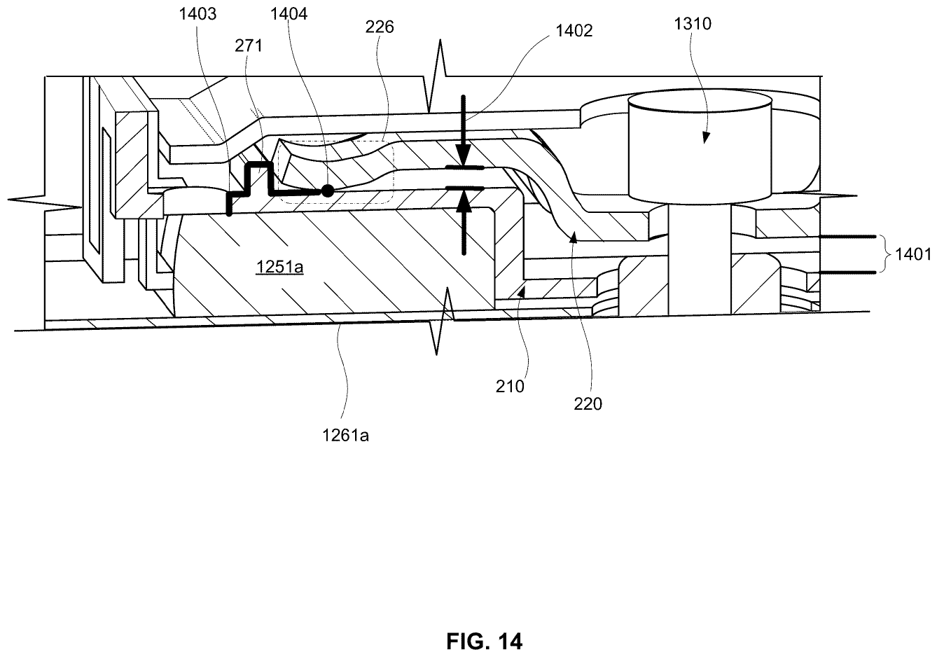

FIGS. 13-14 show cross-sectional views of an illustrative bracket assembly mounted to a PCBA, and applying pressure to a thermal interface, in accordance with some embodiments of the present disclosure. For example, FIG. 13 illustrates some aspects of bracket 200, process 1200, and step 1210 thereof. It will be understood that all feature numbers of bracket 200 are not necessarily called out in FIG. 13 and may be referred to in FIGS. 2-10. As illustrated, a bracket assembly including one of bracket 200, with electronic devices 1251a and 1251b (e.g., which may be switching devices such as MOSFETs) of plurality of electronic devices of plurality of bracket assemblies 1251 installed, is mounted against PCBA 1252. For example, feature 212 was engaged with PCBA 1252, and electronic devices 1251a and 1251b were soldered onto corresponds terminals of PCBA 1252 (e.g., and feature 212 may be, but need not be still engaged). Also as illustrated, PCBA 1252 was installed such that plurality of electronic devices of plurality of bracket assemblies 1251 are aligned with plurality of TIM regions 1261 (e.g., of which TIM region 1261a and 1261b are two).

In some embodiments, as illustrated in FIG. 13, fastener 1310 includes head 1311 and threaded section 1312, and may be used to apply interfacial pressure between electronic devices 1251a and 1251b and respective TIM regions 1261a and 1261b. For example, fastener 1310 may be installed through hole 1315 in PCBA 1252, hole 235 in cover 230, hole 225 in flexure element 220, and hole 255 of body 210, and then threaded section 1312 may engage with threads of hole 1263 while head 1311 engages middle section 223 of flexure element 220. Force F1 (e.g., illustrated by vertical arrows in FIG. 13) may be applied to middle section 223 of flexure element 220 (e.g., by turning fastener 1310 with torque T1), which may cause sections 221 and 222 to press against respective regions 261 and 262. To illustrate, regions 228 and 226 contact and transmit respective forces F2 and F3 to respective regions 261 and 262 (e.g., along a line of contact extending laterally across flexure element 220). These respective forces cause platforms 251 and 252 to press respective electronic devices 1251a and 1251b into respective TIM regions 1261a and 1261b (e.g., in a direction away from the PCBA). For example, hole 225 may accommodate the fastener threads but may have a smaller diameter than head 1311, while hole 235 and hole 1315 in PCBA 1252 may have diameters greater than the diameter of head 1311.

In some embodiments, as illustrated in FIG. 14, gap 1401 between middle section 223 of flexure element 220 and middle section 250 of body 210 may be such that flexure element 220 may be deformed up to a predetermined distance. For example, flexure element 220 may be deformed until middle section 223 bottoms out on middle section 250 (e.g., gap 1401 is reduced to zero by tightening fastener 1310). In some embodiments, gap 1402 is also designed or otherwise predetermined to allow the deformation of flexure element 220 as fastener 1310 is tightened. Contact area 1404 (e.g., extending along a line directed substantially into and out of the page, laterally across flexure element 220) forms between region 226 of flexure element 220 and region 261 behind platform 251. Gap 1403 between contact area 1404 and electronic devices 1251a, and extending around rib 271, may be designed or otherwise predetermined to ensure a minimum electrical creepage path is maintained (e.g., to prevent shorting of high-voltage circuits). To illustrate, gap 1403 may be the same as creepage path 1159 of FIG. 11.

The foregoing is merely illustrative of the principles of this disclosure and various modifications may be made by those skilled in the art without departing from the scope of this disclosure. The above-described embodiments are presented for purposes of illustration and not of limitation. The present disclosure also can take many forms other than those explicitly described herein. Accordingly, it is emphasized that this disclosure is not limited to the explicitly disclosed methods, systems, and apparatuses, but is intended to include variations to and modifications thereof, which are within the spirit of the following claims.

What is claimed is:

1. A bracket comprising:
a body configured to interface with at least one electronic device on a first side and comprising a recess on a second side;
a flexure element arranged in the recess; and
a cover arranged over the flexure element such that the flexure element is arranged between the body and the cover.

2. The bracket of claim 1, wherein the body further comprises at least one platform arranged on the first side and configured to interface with the at least one electronic device.

3. The bracket of claim 1, wherein the body further comprises at least one mounting feature extending from the second side and configured to engage with a printed circuit board assembly, wherein the body is comprised of an electrically insulative material.

4. The bracket of claim 1, wherein:
the body comprises a plastic material that is electrically insulative; and
the cover comprises the plastic material.

5. The bracket of claim 1, wherein the flexure element comprises a metal spring.

6. The bracket of claim 1, wherein the body further comprises at least one rib arranged in the recess and configured to maintain a gap between an end of the flexure element and the at least one electronic device.

7. The bracket of claim 1, wherein the body further comprises at least one retaining feature configured to retain the at least one electronic device.

8. The bracket of claim 1, wherein the body further comprises at least one cover feature configured to secure the cover against the body.

9. The bracket of claim 1, wherein:
the flexure element comprises at least one section arranged to align with the at least one electronic device on the second side;
the flexure element is configured to apply a force on the body; and
the body transmits the force to the at least one electronic devices.

10. The bracket of claim 1, wherein:
the body comprises a first hole;
the flexure element comprises a second hole comprising a second hole diameter and that is aligned with the first hole when the flexure element is arranged in the recess; and
the cover comprises a third hole comprising a third hole diameter and that is aligned with the first hole when the cover is arranged over the flexure element, wherein the second hole diameter is lesser than the third hole diameter.

11. The bracket of claim 10, wherein the bracket is configured to receive a fastener comprising a head and a threaded length, wherein:
the threaded length is configured to extend through the first hole, the second hole, and the third hole and engage with threads of a heat sink; and
the head is configured to engage with the flexure element to apply a force on the flexure element towards the heat sink.

12. An apparatus comprising:
a first platform arranged on a first side configured to receive a first power electronic device;
a second platform arranged on the first side configured to receive a second power electronic device; and
at least one mounting feature arranged on a second side opposite the first side and extending from the second side to engage a printed circuit board assembly.

13. The apparatus of claim 12, further comprising a flexure element arranged on the second side behind the first and second platforms, wherein:
the flexure element comprises two sections configured to apply respective forces on the second side behind the first and second platforms; and
the respective forces cause the first and second power electronic devices to press against respective heat sinks.

14. The apparatus of claim 13, further comprising a hole extending through the flexure element and configured to receive a fastener, wherein the fastener is configured to apply a force on the flexure element to cause the flexure element to apply the respective forces on the second side behind the first and second platforms.

15. The apparatus of claim 13, further comprising:
a first rib arranged proximal to a first end of the flexure element and configured to maintain a first gap between the first end and the first power electronic device; and
a second rib arranged proximal to a second end of the flexure element, opposite the first end, and configured to maintain a second gap between the second end and the second power electronic device.

16. The apparatus of claim 13, wherein:
the flexure element comprises a middle section arranged between the two sections;
the two sections comprise a first section arranged behind the first platform and comprising a first curve such that when a force is applied to the middle section in a first direction, the first section applies a first force to the first platform in substantially the first direction; and
the two sections comprise a second section arranged behind the second platform and comprising a second curve such that when the force is applied to the middle section, the second section applies a second force to the second platform in substantially the first direction.

17. A system comprising:
a heat sink comprising a plurality of thermal interface regions configured to interface to a plurality of electronic devices; and
a power electronics printed circuit board assembly comprising a plurality of brackets, each bracket comprising:
a respective body configured to interface with at least one electronic device, of the plurality of electronic devices, on a first side and comprising a respective recess on a second side;
a respective flexure element arranged in the respective recess; and
a respective cover arranged over the respective flexure element such that the respective flexure element is arranged between the respective body and the respective cover.

18. The system of claim 17, wherein the respective body further comprises at least one rib arranged in the respective recess and configured to maintain a gap between an end of the respective flexure element and the at least one electronic device.

19. The system of claim 17, wherein:
the respective body comprises a first hole;
the respective flexure element comprises a second hole that is aligned with the first hole when the respective flexure element is arranged in the recess; and
the respective cover comprises a third hole that is aligned with the first hole when the respective cover is arranged over the respective flexure element, wherein the second hole is smaller than the third hole.

20. The system of claim 19, further comprising a fastener comprising a head and a threaded length, wherein:
the threaded length is configured to extend through the first hole, the second hole, and the third hole and engage with the heat sink; and
the head is configured to engage with the flexure element to apply a force on the flexure element towards the heat sink.
